(19) United States
(12) Patent Application Publication
(10) Pub. No.: US 2016/0365415 A1
(43) Pub. Date: Dec. 15, 2016

(54) MANUFACTURING METHOD OF GRAPHENE DEVICE

(71) Applicant: ELECTRONICS AND TELECOMMUNICATIONS RESEARCH INSTITUTE, Daejeon (KR)

(72) Inventors: Se Rin PARK, Daejeon (KR); Choon Gi CHOI, Daejeon (KR)

(73) Assignee: ELECTRONICS AND TELECOMMUNICATIONS RESEARCH INSTITUTE, Daejeon (KR)

(21) Appl. No.: 15/176,127

(22) Filed: Jun. 7, 2016

(30) Foreign Application Priority Data
Jun. 11, 2015 (KR) 10-2015-0082522
Mar. 9, 2016 (KR) 10-2016-0028517

(51) Int. Cl. H01L 29/16; H01L 21/02; H01L 29/66; H01L 29/786; H01L 29/417

(52) U.S. Cl. CPC H01L 29/1606; H01L 29/78684; H01L 29/78696; H01L 29/41733; H01L 29/66045; H01L 21/0243; H01L 21/02527; H01L 21/0262

(57) ABSTRACT

A graphene device is manufactured by forming on a substrate a pattern with a material that contains carbon, and growing graphene on the substrate where the pattern is formed.

### CROSS-REFERENCE TO RELATED APPLICATION

The present application claims priority to Korean Patent Application Numbers 10-2015-0082522 filed on Jun. 11, 2015 and 10-2016-0028517 filed on Mar. 9, 2016, in the Korean Intellectual Property Office, the entire disclosure of which is incorporated by reference herein in their entirety.

### BACKGROUND

Field of Invention

The present disclosure relates to a method for manufacturing graphene device, and more particularly, to a method for manufacturing a graphene device having a single layered graphene and multiple layered graphene, at the same time.

Description of Related Art

Recently, studies are being made actively on developing a flexible and transparent electrode that could satisfy mechanical flexibility, and optical and electrical requirements and the like necessary for commercializing flexible and transparent displays, wearable electronic devices etc.

Industries require transparent electrodes to have an optical transmittance of at least 85% and a sheet resistance of not more than 15Ω/cm², but conventional transparent electrodes satisfying such requirements have a disadvantage that they may break easily when bent or curved. Furthermore, conventional transparent electrodes exhibit degraded performance when applied to flexible substrates, and therefore cannot be used for flexible displays and the like.

Therefore, graphene is being developed as a material having conductivity so as to be used in electrodes, but also having high transmittance and flexibility at the same time.

### SUMMARY

A purpose of the present disclosure is to provide a method for easily manufacturing a graphene device without having to go through a complicated process.

According to an embodiment of the present disclosure, a method for manufacturing a graphene device is provided, the method including forming on a substrate a pattern with a material containing carbon; and growing graphene on the substrate where the pattern is formed.

According to the embodiment of the present disclosure, the pattern may be drawn by the material containing the carbon.

According to the embodiment of the present disclosure, the pattern may be printed by a printer.

According to the embodiment of the present disclosure, the pattern may be formed by at least one of photolithography, E-beam lithography, and drawing lithography.

According to the embodiment of the present disclosure, the substrate may include a metal catalyst layer, and the pattern may be provided on the metal catalyst layer. The metal catalyst layer may include copper (Cu), nickel (Ni), cobalt (Co), iron (Fe), platinum (Pt), gold (Au), aluminum (Al), chromium (Cr), magnesium (Mg), manganese (Mn), rhodium (Rh), tantalum (Ta), titanium (Ti), tungsten (W), uranium (U), vanadium (V), or zirconium (Zr), or a combination thereof. According to the embodiment of the present disclosure, the metal catalyst layer may particularly include copper.

According to the embodiment of the present disclosure, the graphene may be transferred to a target substrate. The step of transferring the graphene to the target substrate may include forming a carrier film on the graphene; removing the metal catalyst layer; placing the graphene and the target substrate to face each other, and then compressing the graphene and the target substrate against each other; and removing the carrier film.

According to the embodiment of the present disclosure, the carrier film may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. According to the embodiment of the present disclosure, the carrier film may particularly be polymethyl methacrylate.

According to the embodiment of the present disclosure, the metal catalyst layer may be removed by wet etching.

According to the embodiment of the present disclosure, the graphene may be grown by chemical vapor deposition.

According to the embodiment of the present disclosure, substrate may include a first region where the material is provided, and a second region where the material is not provided, multiple-layer graphene formed in the first region, and single-layer graphene formed in the second region.

According to the embodiment of the present disclosure, the target substrate may have flexibility.

The aforementioned embodiments of the present disclosure provide a method for easily manufacturing a single-layer/multiple-layer graphene in a desired pattern.

### BRIEF DESCRIPTION OF THE DRAWINGS

The above and other features and advantages of the present disclosure will become more apparent to those of ordinary skill in the art by describing in detail embodiments with reference to the attached drawings in which:

FIGS. 1A to 1H are cross-sectional views illustrating a method for manufacturing a graphene device according to an embodiment of the present disclosure;

FIG. 2 is a photograph of a pattern formed on a substrate using a material that includes carbon;

FIG. 3 is a photograph view of an area of a graphene formed by a chemical vapor deposition after forming a pattern using a pencil on a copper foil as a substrate;

FIG. 4 is a Raman spectrum showing measurements of the portion indicated by the square and of the portion indicated by the circle in FIG. 3.

FIG. 5 is a photograph view of an area of a graphene formed by a chemical vapor deposition after forming a pattern using a marker pen on a copper foil as a substrate; and

FIG. 6 is a Raman spectrum showing measurements of the square portion and the circular portion of FIG. 5.

### DETAILED DESCRIPTION

Various modifications and changes may be applied to the exemplary embodiments in accordance with the concept of the present invention so that the exemplary embodiments will be illustrated in the drawings and described in detail in the specification. However, the embodiments according to the concept of the present invention is not limited to the specific embodiments, but includes all changes, equivalents, or alternatives which are included in the spirit and technical scope of the present invention.

Like reference numerals in the drawings denote like elements. Terminologies such as first or second may be used to describe various components but the components are not limited by the above terminologies. The above terminologies are used to distinguish one component from the other component, for example, a first component may be referred to as a second component without departing from a scope in accordance with the concept of the present invention and similarly, a second component may be referred to as a first component. A singular expression includes a plural expression unless clearly defined otherwise.

In the present specification, it should be understood that terms “include” or “have” indicate that a feature, a number, a step, an operation, a component, or a part or a combination thereof described in the specification is present, but do not exclude a possibility of presence or addition of one or more other features, numbers, steps, operations, components, or parts or combinations thereof, in advance. Furthermore, it should be understood that when it is described that a layer, a film, an area, or a panel and the like is “on” another portion, the layer, the film, the area, or the panel and the like may be “directly on” the other portion, or there may also exist another portion therebetween. Furthermore, it should be understood that when it is described that a layer, a film, an area, or a panel and the like is “on” another portion, the layer, the film, the area, or the panel and the like may be on the other portion in an upper direction or in a lower direction. Likewise, it should be understood that when it is described that a layer, a film, an area, or a panel and the like is “below” another portion, the layer, the film, the area, or the panel and the like may be “directly below” the other portion or there may exist another portion therebetween.

Hereinafter, a preferable embodiment of the present disclosure will be explained in further detail with reference to the drawings attached.

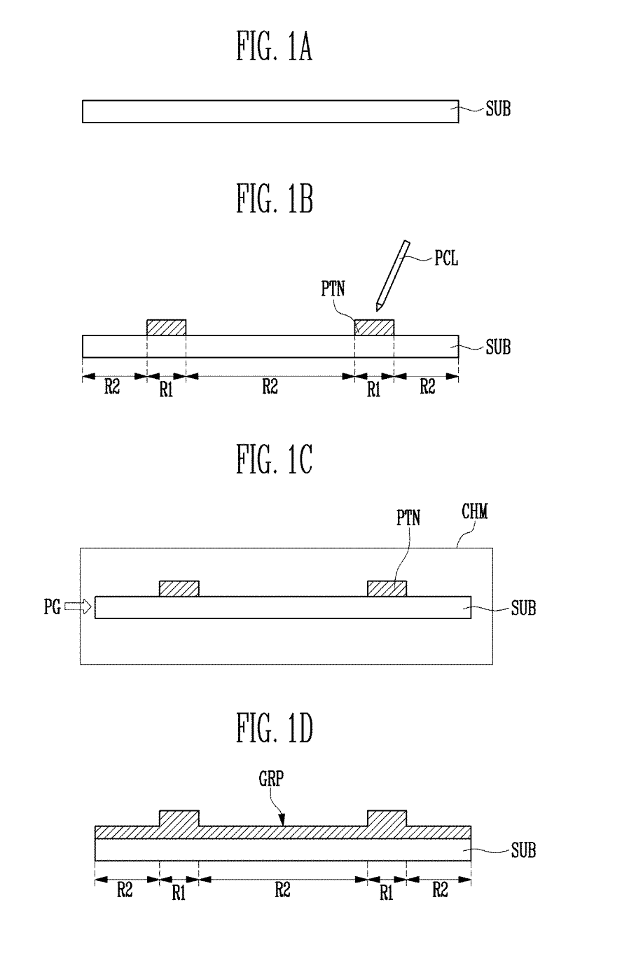

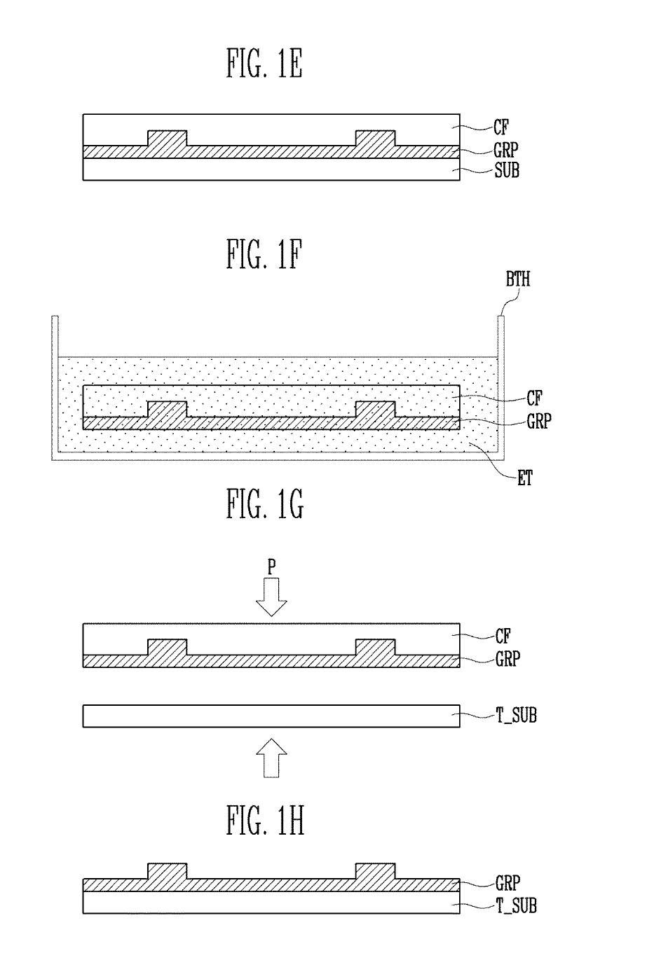

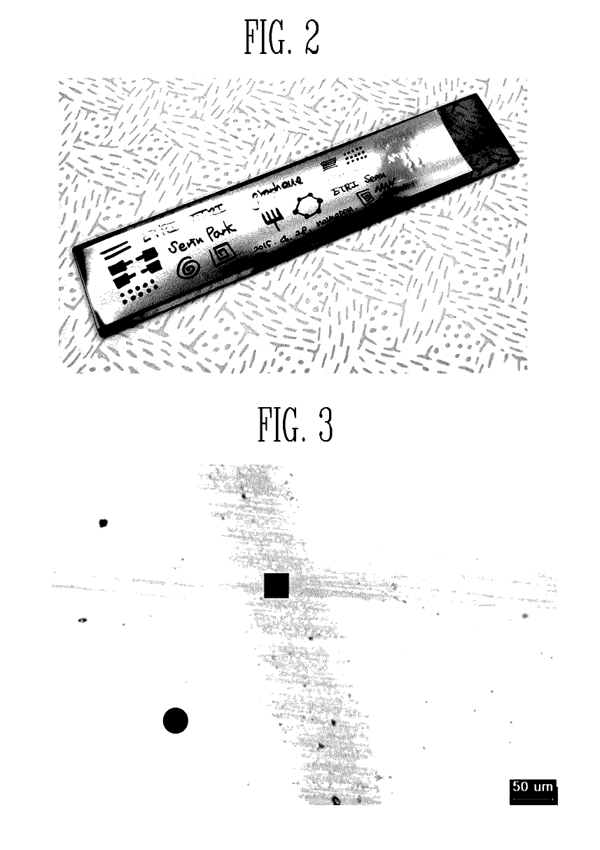

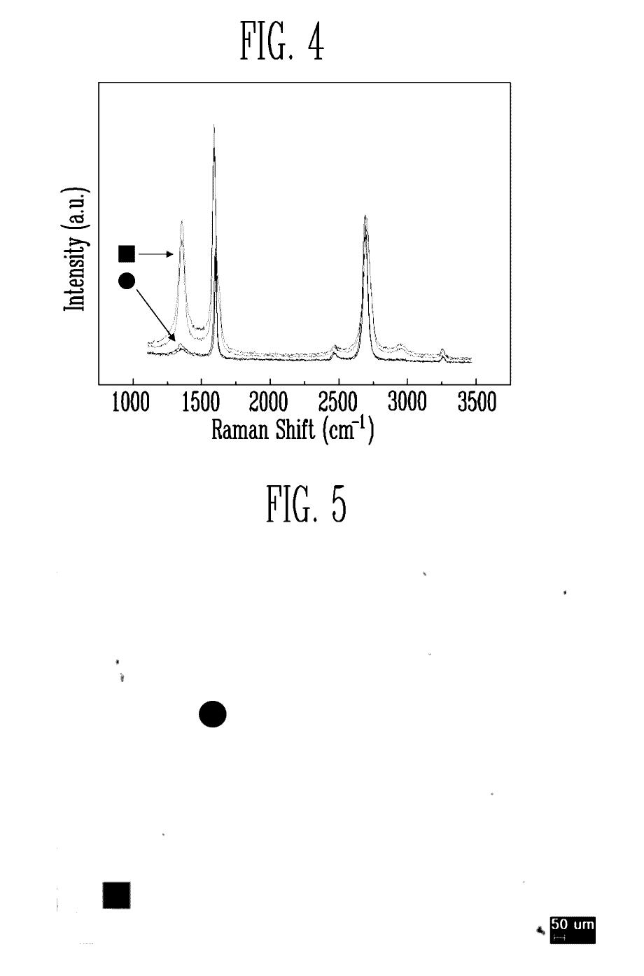

FIGS. 1A to 1H are cross-sectional views illustrating a method for manufacturing a graphene device according to an embodiment of the present disclosure.

Referring to FIG. 1A, a substrate SUB for growing graphene is prepared.

The substrate SUB is to grow graphene on its upper surface. The material of the substrate is not limited as long as graphene grows.

In an embodiment of the present disclosure, the substrate SUB may include a metal catalyst layer.

The metal catalyst layer includes metal or a metal alloy capable of growing the graphene. The metal catalyst layer may include copper (Cu), nickel (Ni), cobalt (Co), iron (Fe), platinum (Pt), gold (Au), aluminum (Al), chromium (Cr), magnesium (Mg), manganese (Mn), rhodium (Rh), tantalum (Ta), titanium (Ti), tungsten (W), uranium (U), vanadium (V), or zirconium (Zr), or a combination thereof. In an embodiment of the present disclosure, the metal catalyst layer may comprise copper, in which case the substrate SUB may be provided in the form of copper foil.

Referring to FIG. 1B, with the material that includes carbon, a pattern PTN is formed on the substrate SUB.

The pattern PTN is formed only in areas for where graphene of multiple layers is to be formed. In an embodiment of the present disclosure, if the area where the pattern PTN is formed is referred to as a first region R1 and the area where the pattern PTM is not formed is referred to as a second region R2, in a subsequent process, the graphene of multiple layers is formed only in the first region R1, whereas the graphene of a single layer is formed in the second region R2. This will be explained in further detail later on.

The pattern PTN may be formed manually and/or automatically.

In an embodiment of the present disclosure, the pattern PTN may be drawn with a pencil, charcoal, a marker pen, a fountain pen, or a quill pen and the like. Pencils contain graphite, while charcoal contains carbon originated from wood. In the marker pen, the fountain pen, and the quill pen and the like, ink for writing is used. The ink for writing may contain a material including carbon such as carbon black and the like.

FIG. 1B illustrates the concept of forming the pattern PTN with a pencil PCL for the convenience of the explanation.

In an embodiment of the present disclosure, the pattern PTN may be printed by a printer. The ink to be used in an inkjet printer may include carbon powder such as carbon black.

In an embodiment of the present disclosure, the pattern PTN may be formed by at least one method of photolithography, E-beam lithography, and drawing lithography. The pattern PTN may be formed by depositing a material layer, which may contain carbon, on the substrate SUB and then patterning the material layer in the aforementioned lithography method. The material layer containing carbon may be deposited using gas that contains carbon.

In the case of forming the pattern PTN using the printer or the lithography method, a more detailed and precise patterning is possible compared to when using a tool such as the pencil PCL.

Then, by putting the substrate SUB where the pattern PTN is formed inside the chemical vapor deposition apparatus as illustrated in FIG. 1C, the graphene GRP is formed on the substrate SUB as illustrated in FIG. 1D.

Referring to FIG. 1C and FIG. 1D, the graphene GRP is formed on the substrate SUB by the chemical vapor deposition method.

The graphene GRP has a plurality of carbon atoms connected in covalent bonds, with a structure aligned on a 2-dimensional plane. Most of the carbon atoms connected in covalent bonds form hexagonal rings, but some may form pentangular rings and/or heptangular rings as well.

Growing the graphene GRP may be performed in various methods including for example the chemical vapor deposition (CVD) method. Examples of the chemical vapor deposition method include thermal chemical vapor deposition (TCVD), rapid thermal chemical vapor deposition (RTCVD), inductive coupled plasma enhanced chemical vapor deposition (ICP-PECVD) and the like.

In an embodiment of the present disclosure, the graphene GRP may be formed by placing inside a chamber CHM of the chemical vapor deposition apparatus the substrate SUB on which the pattern PTN is formed, and inserting a process gas PG into the chamber CHM and then applying heat thereto. The process gas PG is a type of gas that contains carbon. Hydrogen and CH₄, C₂H₂, C₂H₄, CO and the like may be used as the process gas PG.

In an embodiment of the present disclosure, in the case of forming the graphene GRP in the chemical vapor deposition method, the graphene GRP may be formed at a temperature of 1,000° C. on a substrate, such as a copper foil, under an atmosphere of hydrogen and methane. The growth condition of graphene GRP corresponds to the synthesizing condition of a single-layer graphene GRP, and thus the graphene GRP is easily synthesized on an entirety of surface of the substrate SUB where the pattern PTN is or is not formed. However, since there is a large amount of carbon in the first region R1 where the pattern PTN is formed, multiple-layer graphene GRP of at least two layers is synthesized. In other words, the graphene GRP is formed to have different layers depending on whether or not there is a pattern PTN. Therefore, in the first region R1 where the pattern PTN is formed, the graphene GRP of multiple layers is formed, while in the second region R2 where the pattern PTN is not formed, the graphene GRP of a single layer is formed. The graphene GRP of multiple layers and the graphene GRP of a single layer are formed simultaneously at the chemical vapor depositing step.

As aforementioned, according to the embodiments of the present disclosure, it is possible to obtain graphene GRP of multiple layers and graphene of a single layer in a simple manner, and it is also possible to adopt the graphene to various elements.

The graphene manufactured in the aforementioned method has a high charge transfer rate (about 200,000 cm²/Vs) and a high heat conductivity (about 5,000 W/mK). Furthermore, not only does the aforementioned graphene have a high chemical resistance, but it is also capable of various chemical functionalizations.

Since the graphene has the aforementioned physical properties, it may replace conventional transparent electrodes. Especially, even though the graphene does not have a band gap and thus absorbs light of entire wavelength areas, the thickness of the graphene GRP of a single layer is only the thickness of one layer, and thus the transparency is as high as 97.7%. Therefore, the graphene may be applied to elements that require a high transparency. Furthermore, since the graphene GRP has a high flexibility (about 25%), it may also be applied to flexible devices.

In conventional inventions, numerous complicated manufacturing processes had to be performed in order to utilize graphene as a device. For example, it was necessary to transfer graphene on top of a substrate and then perform a process of patterning a photosensitizer and depositing a metal and the like on top of the graphene in order to form a graphene device. These processes do not guarantee physical/chemical stability of the graphene device, and it takes too much time and costs. Therefore, there were problems that it was not easy to manufacture a device using graphene, and even if a graphene device was made, the yield rate was very low.

According to an embodiment of the present disclosure, it is possible not to go through a complicated process of forming an electrode or a channel. In an embodiment of the present disclosure, since it is easy to form graphene GRP having multiple layers and/or a single layer in different areas, it is possible to control the number of layers of the graphene to be finally formed according to the concentration and thickness of the pattern formed on the first region, for example. In an embodiment of the present disclosure, the graphene of multiple layers formed in the first region may be used as for example a source electrode and/or drain electrode of a thin film transistor, and the single-layer graphene formed in the second region may be used as a channel of the thin film transistor.

As such, since there is no need for a separate metal deposition process to form a multiple-layer graphene to serve as an electrode, it is possible to reduce the process time and costs far more than conventional methods, and there is an advantage that by applying the single-layer and/or multiple-layer graphene to devices such as a channel, source, drain and the like, it is possible to obtain a graphene device in a simple manner without an additional process.

Since the graphene manufactured in the aforementioned process may be transferred to various types of devices and used, a method for transferring the graphene will be explained hereinafter.

Referring to FIG. 1E, a carrier film CF is formed on top of the substrate SUB where the graphene GRP is formed. The carrier film CF is used for moving the graphene GRP to a target substrate, but the carrier film CF is removed at the final step.

The carrier film CF may or may not have flexibility, and may comprise an organic and/or inorganic polymer.

In the embodiment of the present disclosure, the carrier film CF may include at least one of polystyrene, polyvinyl alcohol, polyamide, polymethyl methacrylate, polysulfone, polyethersulfone, polyetherimide, polyether etherketone, polyethylene, polyacrylate, polyethylenenaphthlate, polyethylene terephthalate, polypropylene, polybutylene terephthalate, polypenylene sulfide, polyarylate, polyimide, polycarbonate, polylactide, triacetate cellulose, cellulose acetate propionate, polydimethyl siloxane, and cyclo olefin copolymer.

In an embodiment of the present disclosure, the carrier film CF may be polymethyl methacrylate.

The carrier film CF may be formed on the pattern PTN in various methods. For example, the carrier film CF may be provided in a fluid form and applied on the pattern PTN, and then hardened.

However, the carrier film CF is not limited to the aforementioned.

That is, a material other than the aforementioned may be used as long as it may be used to transfer the graphene GRP to the target substrate T_SUB. For example, the carrier film CF may be a thermal release tape. The thermal release tape may be one that is in commercial use and that has adhesion at a certain temperature, but that loses the adhesion when heated above a certain temperature.

Referring to FIG. 1F, the substrate SUB is removed. The substrate SUB may be removed in various methods for example, wet etching, or dry etching, or a combination thereof.

In the embodiment of the present disclosure, since the substrate SUB contains the metal catalyst layer for growing the graphene GRP, the metal catalyst layer may be removed by the wet etching. The etching solution ET to be used in the wet etching may vary depending on the metal included in the metal catalyst layer.

The wet etching may be performed by spraying the etching solution ET on a rear face of the substrate SUB, or by placing the substrate SUB inside a bath that contains the etching solution ET. In the case of spraying the etching solution ET on the rear face of the substrate SUB, the substrate SUB may be removed with a small amount of etching solution ET.

FIG. 1F illustrates an example of removing the substrate SUB by placing the substrate SUB inside a bath BTH in which case the surface area of the substrate SUB that contacts the etching solution ET is increased, and thus the etching may be performed quickly.

In the embodiment of the present disclosure, the etching solution ET may be at least one of ammonium persulfate ((NH₄)₂S₂O₈) solution, sodium persulfate (Na₂S₂O₈) solution, iron chloride (FeCl₃) solution, iron nitride (Fe(NO₃)₃) solution, copper chloride (CuCl₂) solution, and sulfuric acid/hydrogen peroxide mixed solution.

In the embodiment of the present disclosure, after the etching, a washing process and a drying process for removing the etching solution ET may be further conducted in order to remove residual solution. The washing process may be performed using deionized water.

Referring to FIG. 1G, a target substrate T_SUB to which the graphene GRP is to be transferred is prepared, and then the graphene GRP and the target substrate T_SUB are placed to face each other. Then, the graphene GRP is transferred by compression process of the graphene GRP and the target substrate T_SUB.

The target substrate T_SUB is, where the graphene GRP should be finally formed, may include silicon oxide, silicon nitride, metal oxide (for example, hafnium oxide, zirconium oxide), glass, crystal, organic and/or inorganic polymer, metal and the like. The target substrate T_SUB may have flexibility, and may comprise a transparent or nontransparent material.

In an embodiment, the target substrate T_SUB may comprise a polymer organic material. Examples of insulating substrate materials containing the polymer organic material include polystyrene, polyvinyl alcohol, polyamide, polymethyl methacrylate, polysulfone, polyethersulfone, polyetherimide, polyetheretherketone, polyethylene, polyacrylate, polyethylene naphthlate, polyethylene terephthalate, polypropylene, polybutylene terephthalate, polypenylene sulfide, polyarylate, polyimide, polycarbonate, polylactide, triacetate cellulose, celluloseacetate propionate, polydimethylsiloxane, and cyclo olefin copolymer. But, the insulating substrate materials are not limited thereto. For example the first substrate SUB may comprise fiber glass reinforced plastic FRP in an embodiment.

In an embodiment of the present disclosure, the target substrate T_SUB may be an insulating substrate comprising SiO₂.

The compression process may be performed by arranging an exposed portion of the graphene GRP and the target substrate T_SUB to face each other, and then by applying pressure P in a direction that the graphene GRP and the target substrate T_SUB face each other or in an opposite direction thereof. In an embodiment of the present disclosure, the compression process may be performed using a roller.

In an embodiment of the present disclosure, in order to improve the adhesion between the graphene GRP and the target substrate T_SUB, a plasma processing may be further performed to the target substrate T_SUB and/or the graphene GRP.

Referring to FIG. 1H, the transferring of the graphene GRP is completed as the carrier film CF is removed from the graphene GRP.

As aforementioned, according to an embodiment of the present disclosure, it is possible to synthesize multiple-layer graphene and single-layer graphene in a simple method, and apply the graphene in manufacturing a device easily without any further process.

The graphene formed by the aforementioned method may be applied to devices that use graphene, for example, various electronic devices including transistors, bio engineering, energy storage, optical cells, and the like.

Furthermore, in the case where graphene is formed with a great thickness, it is possible to strip only a portion where the graphene is formed thick during the manufacturing process. Accordingly, in an embodiment of the present disclosure, it is possible to manufacture various types of patterns using such a stripping process. Especially, when forming a pattern, when the concentration of the carbon in the material containing carbon is too high or when the material containing carbon is patterned thick, it is possible to easily strip a certain portion during the process of removing the carrier film. Utilizing this characteristic, it is advantageous in providing various patterns in areas where graphene is not needed.

### Embodiment

First of all, a copper foil having a thickness of 25 μm and a certain surface area was prepared as substrate, and then a desired pattern was drawn on the copper foil by hands using a marker pen and a pencil.

FIG. 2 is a photograph of a pattern formed on a substrate using a material that includes carbon.

In an embodiment of the present disclosure, the pattern is drawn using the marker pen and the pencil, but in another embodiment, an inkjet printer may be used, in which case more detailed and various patterns may be obtained.

In this embodiment, the patterned substrate was placed into a chamber of a chemical vapor deposition apparatus and then maintained at a vacuum state. Then, at a temperature of 1,000° C. and under an atmosphere of hydrogen and methane, graphene was synthesized for 20 minutes. When synthesizing the graphene, the pressure inside the chamber was maintained at about a vacuum of about 10⁴ ton, and the hydrogen and the methane injected were 10 sccm and 30 sccm respectively. After the 20 minutes, gas supply to the chamber of the chemical vapor deposition apparatus was stopped, and the temperature was lowered to room temperature at a velocity of about 25° C./minute.

FIG. 3 is an enlarged photograph view of an area of graphene formed by a chemical vapor depositing apparatus after forming a pattern using a pencil and a copper foil as substrate.

Referring to FIG. 3, the relatively darker portion (the portion indicated by a square) corresponds to an area where multiple-layer graphene, that is, the first region is formed, and the relatively brighter portion (the portion indicated by the circle) corresponds to an area where single-layer graphene, that is, the second region is formed. Whether or not graphene is formed in the first region and in the second region was confirmed by the result of the Raman spectrum.

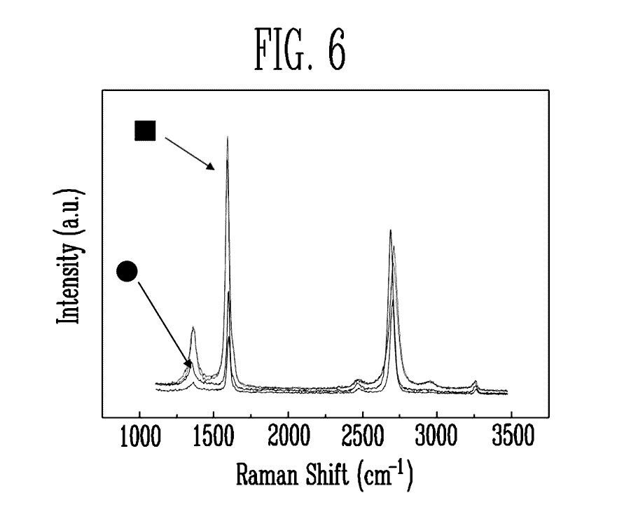

FIG. 4 is a Raman spectrum showing measurements of the portion indicated by the square and of the portion indicated by the circle in FIG. 3.

Referring to FIG. 4, peaks were confirmed at around 1,600 cm⁻¹ and at around 2,700 cm⁻¹ that correspond to G band and 2D band respectively, whereby one can see that graphene is synthesized. Furthermore, considering the ratio of the two bands, one can see that single-layer graphene is formed in the portion indicated by the circle, and multiple-layer graphene is formed in the portion indicated by the square.

FIG. 5 is an enlarged photograph view of an area of graphene formed by a chemical vapor depositing apparatus after forming a pattern using a marker pen on a copper foil as substrate.

In the present embodiment, graphene was also formed in the aforementioned method. That is, a substrate on which a pattern is drawn was put into a chamber of a chemical vapor apparatus, and then maintained at a vacuum state. Then, graphene was synthesized for 20 minutes at a temperature of 1,000° C. and under an atmosphere of hydrogen and methane. When synthesizing the graphene, the pressure inside the chamber was maintained at vacuum state of about 10⁻⁴ ton, and the amount of hydrogen and methane injected were 10 sccm and 30 sccm respectively. After the aforementioned 20 minutes of synthesizing the graphene, gas supply to the chamber inside the chemical vapor apparatus was stopped, and the temperature was lowered to room temperature at a velocity of about 25° C./minute.

Referring to FIG. 5, the relatively darker portion (the portion indicated by a square) corresponds to an area where multiple-layer graphene, that is, a first region is formed, and the relatively brighter portion (the portion indicated by the circle) corresponds to an area where single-layer graphene, that is, a second region is formed. Whether or not graphene is formed in the first region and in the second region was confirmed by the result of the Raman spectrum.

FIG. 6 is a Raman spectrum showing measurements of the portion indicated by the square and of the portion indicated by the circle in FIG. 5.

Referring to FIG. 6, peaks were confirmed at around 1,600 cm⁻¹ and at around 2,700 cm⁻¹ that correspond to G band and 2D band respectively, whereby one can see that graphene is synthesized. Furthermore, considering the ratio of the two bands, one can see that single-layer graphene is formed in the portion indicated by the circle, and multiple-layer graphene is formed in the portion indicated by the square.

Referring to FIG. 6, one can see that the number of layers of the graphene differ depending on the concentration and the thickness of ink. Therefore, in the case of forming a pattern using the marker pen or the inkjet printer and the like, the pattern may be formed thick or thin as necessary, according to which the number of layers of the graphene will differ.

In the drawings and specification, there have been disclosed typical embodiments of the invention, and although specific terms are employed, they are used in a generic and descriptive sense only and not for purposes of limitation. It will be understood by those of ordinary skill in the art that various changes in form and details may be made therein without departing from the spirit and scope of the present invention as defined by the following claims.

As for the scope of the invention, it is to be set forth in the following claims.

What is claimed is:

1. A method for manufacturing a graphene device, the method comprising:
forming on a substrate a pattern with a material containing carbon; and
growing graphene on the substrate where the pattern is formed.

2. The method according to claim 1,
wherein the pattern is drawn by the material containing the carbon.

3. The method according to claim 1,
wherein the pattern is printed by a printer.

4. The method according to claim 1,
wherein the pattern is formed by at least one of photolithography, E-beam lithography, and drawing lithography.

5. The method according to claim 1,
wherein the substrate comprises a metal catalyst layer, and the pattern is provided on the metal catalyst layer.

6. The method according to claim 5,
wherein the metal catalyst layer comprises copper (Cu), nickel (Ni), cobalt (Co), iron (Fe), platinum (Pt), gold (Au), aluminum (Al), chromium (Cr), magnesium (Mg), manganese (Mn), rhodium (Rh), tantalum (Ta), titanium (Ti), tungsten (W), uranium (U), vanadium (V), or zirconium (Zr), or a combination thereof.

7. The method according to claim 6,
wherein the metal catalyst layer comprises copper.

8. The method according to claim 5,
further comprising a step of transferring the graphene to a target substrate.

9. The method according to claim 8,
wherein the transferring the graphene to the target substrate comprises:
forming a carrier film on the graphene;
removing the metal catalyst layer;
placing the graphene and the target substrate to face each other;
compressing the graphene and the target substrate against each other; and
removing the carrier film.

10. The method according to claim 9,
wherein the carrier film comprises at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

11. The method according to claim 10,
wherein the carrier film is polymethyl methacrylate.

12. The method according to claim 9,
wherein the metal catalyst layer is removed by wet etching.

13. The method according to claim 8,
wherein the target substrate has flexibility.

14. The method according to claim 5,
wherein the graphene is grown by chemical vapor deposition.

15. The method according to claim 1,
wherein the substrate comprises a first region where the material is provided, and a second region where the material is not provided, multiple-layer graphene formed in the first region, and single-layer graphene formed in the second region.
